(19) United States
(12) Patent Application Publication
(10) Pub. No.: US 2023/0343903 A1
(43) Pub. Date: Oct. 26, 2023

(54) FACE-UP LIGHT-EMITTING DEVICE AND DISPLAY DEVICE INCLUDING THE SAME

(71) Applicant: XIAMEN SAN’AN OPTOELECTRONICS CO., LTD., Fujian Province (CN)

(72) Inventors: Qing WANG, Xiamen (CN); Huining WANG, Xiamen (CN); Hongwei XIA, Xiamen (CN); Peng LIU, Xiamen (CN); Chao LU, Xiamen (CN); Ling-Yuan HONG, Xiamen (CN); Chung-Ying CHANG, Xiamen (CN)

(21) Appl. No.: 18/299,321

(22) Filed: Apr. 12, 2023

(30) Foreign Application Priority Data
Apr. 21, 2022 (CN) 202210423283.5
Apr. 21, 2022 (CN) 202220931439.6

(51) Int. Cl. H01L 33/46

(52) U.S. Cl. CPC H01L 33/46; H01L 33/06

(57) ABSTRACT

A face-up light-emitting device includes a substrate, a semiconductor stacked structure, and a first insulating stacked structure. The substrate has a first surface and a second surface opposite to the first surface. The semiconductor stacked structure is disposed on the first surface and is capable of emitting light. The first insulating stacked structure is disposed on the semiconductor stacked structure and includes first material layers each of which has a refractive index, and second material layers each of which has a refractive index higher than that of each of the first material layers. The first insulating stacked structure has a geometric thickness ranging from 500 nm to 1000 nm. The first material layers and the second material layers are stacked alternately. A display device including the face-up light-emitting device is also disclosed.

### CROSS-REFERENCE TO RELATED APPLICATION

This application claims priorities to Chinese Invention Patent Application No. 202210423283.5, filed on Apr. 21, 2022, and Chinese Utility Model Patent Application No. 202220931439.6, filed on Apr. 21, 2022, which are incorporated herein by reference in their entireties.

### FIELD

The disclosure relates to a semiconductor device and a display device including the same, and more particularly to a face-up light-emitting device and a display device including the same.

### BACKGROUND

Light-emitting diodes (LEDs), which have been utilized as light sources, have developed rapidly in the fields of illumination and display devices, especially in the field of backlight devices. In recent years, in the field of backlight devices, the display effect of a display device has been given higher expectations. Mini light-emitting diodes (mini-LEDs), which are developed from conventional LEDs, have the capability of significantly enhancing the display effect of a display device, and hence are quickly promoted.

There are two ways to improve the light-emitting efficiency of the mini-LEDs. One involves using a flip-chip technique, and the other is accomplished by controlling the beam angle of light. The beam angle directly determines various optimal performances of the mini-LEDs.

However, the flip-chip mini-LEDs incur high costs, which is a critical factor that limits the marketplace of backlight devices for downstream manufacturers producing display devices. Therefore, there is an urgent need to design a relatively cheap alternative mini-LEDs, which can not only meet the display requirements, including brightness, luminance uniformity, and product reliability, but also guarantee a lower cost.

### SUMMARY

Therefore, an object of the disclosure is to provide a face-up light-emitting device and a display device including the same that can alleviate at least one of the drawbacks of the prior art.

According to a first aspect of the disclosure, the face-up light-emitting device includes a substrate, a semiconductor stacked structure, and a first insulating stacked structure.

The substrate has a first surface and a second surface opposite to the first surface. The semiconductor stacked structure is disposed on the first surface and is capable of emitting light. The first insulating stacked structure is disposed on the semiconductor stacked structure and includes first material layers each of which has a refractive index, and second material layers each of which has a refractive index higher than that of each of the first material layers. The first insulating stacked structure has a thickness which ranges from 500 nm to 1000 nm. The first material layers and the second material layers are stacked alternately.

According to a second aspect of the disclosure, the display device includes the face-up light-emitting device as mentioned above.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a top schematic view illustrating a first embodiment of a face-up light-emitting device according to the disclosure which includes a first metal electrode and a second metal electrode each of which is disposed on a substrate.

FIG. 2 is a cross-sectional schematic view illustrating the first embodiment of the face-up light-emitting device according to the disclosure, which shows a first wire bonding portion of the first metal electrode.

FIG. 3 is a cross-sectional schematic view illustrating the first embodiment of the face-up light-emitting device according to the disclosure.

FIG. 4 is a cross-sectional schematic view illustrating the first embodiment of the face-up light-emitting device according to the disclosure, in which metal wires are respectively connected to the first metal electrode and the second metal electrode.

FIG. 5 is a graph illustrating geometric thicknesses of a base layer (SiO₂), first material layers (SiO₂) and second material layers (TiO₂) of a first insulating stacked structure in a second embodiment of the face-up light-emitting device according to the disclosure

FIG. 6 is a graph illustrating optimal thicknesses of the base layer (SiO₂), the first material layers (SiO₂) and the second material layers (TiO₂) of the first insulating stacked structure in the second embodiment of the face-up light-emitting device according to the disclosure.

FIG. 7 is a simulation graph illustrating the reflectance of the first insulating stacked structure shown in FIG. 5 to a light that has a wavelength ranging from 370 nm to 600 nm and that has an incident angle ranging from 0° to 60°.

FIG. 8 is a simulation graph illustrating the reflectance of the first insulating stacked structure shown in FIG. 5 to a light that has a wavelength ranging from 370 nm to 1090 nm and that has an incident angle of 10°.

FIG. 9 is a cross-sectional schematic view illustrating a third embodiment of the face-up light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

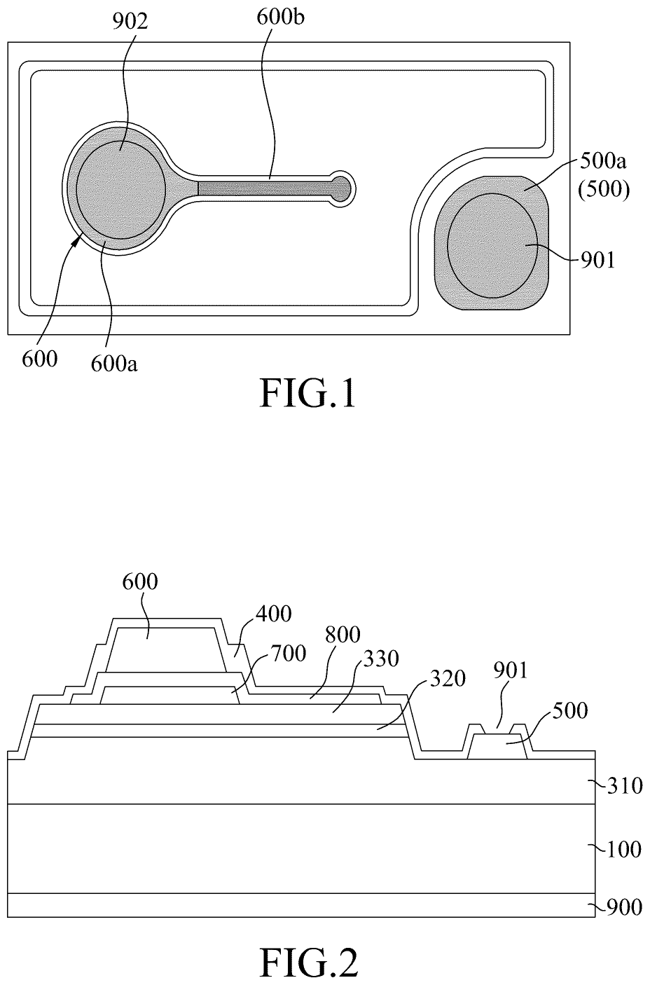

Referring to FIGS. 1 to 3, a first embodiment of a face-up light-emitting device according to the disclosure includes a substrate 100, a semiconductor stacked structure, a first insulating stacked structure 400, a first metal electrode 500, a second metal electrode 600, and a reflecting structure 900.

A manufacturing process for the first embodiment of the face-up light-emitting device according to the disclosure is described below.

Firstly, the substrate 100 is provided. The substrate 100 may be a transparent substrate, e.g., a flat sapphire substrate or a patterned sapphire substrate. The substrate 100 has a first surface and a second surface opposite to the first surface. As shown in FIG. 2, the first surface refers to an upper surface of the substrate 100, and the second surface refers to a lower surface of the substrate 100. In this embodiment, the substrate 100 is a sapphire substrate with the first surface being patterned.

In certain embodiments, the substrate 100 has a thickness greater than 80 μm. In an exemplary embodiment, the substrate 100 has a thickness ranging from 100 μm to 200 μm.

In certain embodiments, the substrate 100 has a length and a width, and the length to the width is in a ratio not less than 2:1. In an exemplary embodiment, the length to the width is in a ratio not greater than 4:1.

Subsequently, the semiconductor stacked structure is formed on the substrate 100. In certain embodiments, the semiconductor stacked structure has a thickness ranging from 3 μm to 10 μm. In an exemplary embodiment, the semiconductor stacked structure has a thickness ranging from 3 μm to 5 μm.

Specifically, the semiconductor stacked structure is disposed on the first surface and is capable of emitting light. In certain embodiments, the face-up light-emitting device is used as a backlight source of a liquid crystal display (LCD). In an exemplary embodiment, the face-up light-emitting device emits light having a wavelength ranging from 420 nm to 480 nm with a peak wavelength ranging from 440 nm to 455 nm.

The semiconductor stacked structure includes a first semiconductor layer 310, an active layer 320, and a second semiconductor layer 330 that are disposed on the first surface of the substrate 100 in a laminating direction in such order. In certain embodiments, the first semiconductor layer 310 is an n-type semiconductor layer, the second semiconductor layer 330 is a p-type semiconductor layer, and the active layer 320 is a multi-layered quantum well structure.

Next, the second semiconductor layer 330 and the active layer 320 are partially removed by an etching technique, such as a dry etching, so as to expose a surface of the first semiconductor layer 310.

Afterwards, a current blocking layer 700 and a transparent conductive layer 800 are sequentially formed on the second semiconductor layer 330. The current blocking layer 700 is located to be aligned with the second metal electrode 600 formed later. In addition, the current blocking layer 700 is configured to partially block a current flowing downward from the second metal electrode 600, which may facilitate the distribution of the current in a horizontal direction. Besides, the current blocking layer 700 may also be formed on the exposed surface of the first semiconductor layer 310. In certain embodiments, the current blocking layer 700 has a thickness ranging from 100 nm to 300 nm. In certain embodiments, the transparent conductive layer 800 has a thickness ranging from 20 nm to 200 nm. The current blocking layer 700 may be made of SiOₓ, and the transparent conductive layer 800 may be made of pure indium tin oxide (ITO) or an ITO doped with aluminum (Al) and/or silver (Ag).

After that, the first metal electrode 500 and the second metal electrode 600 are respectively formed on the exposed surface of the first semiconductor layer 310 and on the transparent conductive layer 800 that is disposed on the second semiconductor layer 330. The first metal electrode 500 and the second metal electrode 600 are respectively in contact with the exposed surface of the first semiconductor layer 310 and the transparent conductive layer 800. For forming the first metal electrode 500 and the second metal electrode 600, photoresist layers with mask patterns are initially formed on the first semiconductor layer 310 and the second semiconductor layer 330, respectively, by means of, for example, exposing and developing techniques using a mask layer. Next, the first metal electrode 500 and the second metal electrode 600 are formed by, e.g., deposition.

Referring to FIG. 1, the first metal electrode 500 includes a first wire bonding portion 500a having a first upper surface, and a first extending portion (not shown) having a first extending surface. The second metal electrode 600 includes a second wire bonding portion 600a having a second upper surface, and a second extending portion 600b having a second extending surface. Each of the first wire bonding portion 500a and the second wire bonding portion 600a may have a cross section that is parallel to the second surface of the substrate 100, and may be in a shape, such as round, horseshoe, polygonal or elliptical. In order to ensure bonding reliability, each of the first upper surface of the first metal electrode 500 and the second upper surface of the second metal electrode 600 may have a width ranging from 30 μm to 80 μm. Also, each of the first extending surface of the first extending portion (not shown) and the second extending surface of the second extending portion 600b may have a width ranging from 2 μm to 5 μm. The transparent conductive layer 800 and the current blocking layer 700 under the second wire bonding portion 600a of the second metal electrode 600 may be removable so that the second wire bonding portion 600a of the second metal electrode 600 may be in direct contact with the second semiconductor layer 330. In addition, the second extending portion 600b of the second metal electrode 600 is disposed on the transparent conductive layer 800 and is in direct contact with the transparent conductive layer 800.

Each of the first wire bonding portion 500a of the first metal electrode 500 and the second wire bonding portion 600a of the second metal electrode 600 may be a metal bonding layer, e.g., a gold bonding layer or an aluminum bonding layer, and has a thickness ranging from 1 μm to 3 μm, e.g., from 1.5 μm to 2.5 μm. In certain embodiments, each of the first wire bonding portion 500a and the second wire bonding portion 600a is a gold bonding layer because gold is stable in nature and has a higher hardness than that of aluminum, which is conducive to bonding strength.

Each of the first metal electrode 500 and the second metal electrode 600 may further include an adhesive layer that is made of, for example, chromium. The adhesive layer may be a lowermost layer of each of the first metal electrode 500 and the second metal electrode 600 for improving the adhesion of the first metal electrode 500 and the second metal electrode 600. In an exemplary embodiment, the adhesive layer has a thickness ranging from 1 nm to 10 nm. Moreover, each of the first metal electrode 500 and the second metal electrode 600 may further include a reflective layer made of, for example, aluminum. In each of the first metal electrode 500 and the second metal electrode 600, the reflective layer is disposed between the adhesive layer and the first/second wire bonding portion 500a/600a. In an exemplary embodiment, the reflective layer has a thickness ranging from 50 nm to 200 nm. In addition, the reflective layer is utilized for reflecting light. Furthermore, each of the first metal electrode 500 and the second metal electrode 600 may further include a blocking layer disposed between the reflective layer and the first/second wire bonding portion 500a/600a. The blocking layer may be a multilayer structure formed by, for example, alternately stacking titanium layers, nickel layers, and platinum layers, alternately stacking titanium layers and platinum layers, or alternately stacking nickel layers and platinum layers. The blocking layer is used to prevent the mutual diffusion of aluminum and gold. In an exemplary embodiment, the blocking layer has a thickness not greater than 1 μm.

In certain embodiments, the first metal electrode 500 has a height ranging from 2 μm to 5 μm in the laminating direction. In certain embodiments, the second metal electrode 600 has a height ranging from 2 μm to 5 μm in the laminating direction. Each of the first metal electrode 500 and the second metal electrode 600 may be a multilayer structure (e.g., having the metal bonding layer, the blocking layer, the reflective layer and the adhesive layer as mentioned above), and the upper one of the layers covers an upper surface and a side wall of the lower one of the layers. It is worth mentioning that the width of a portion of the upper one of the layers covering the side wall of the lower one of the layers may not be too great, otherwise light absorption will occur. In certain embodiments, each of the first metal electrode 500 and the second metal electrode 600 has an inclined side wall.

Afterwards, the first insulating stacked structure 400 is formed. The first insulating stacked structure 400 is disposed on the semiconductor stacked structure, and covers the first upper surface of the first wire bonding portion 500a, the first extending surface of the first extending portion, the second upper surface of the second wire bonding portion 600a, the second extending surface of the second extending portion 600b, the side walls of the first metal electrode 500, and the second metal electrode 600. Briefly, the first insulating stacked structure 400 covers the first metal electrode 500 and the second metal electrode 600. In addition, the first insulating stacked structure 400 also covers a top surface and a side wall of the semiconductor stacked structure. The first insulating stacked structure 400 acts as a passivation layer, cladding the side walls of the first and second metal electrodes 500, 600, and the top surface and the side wall of the semiconductor stacked structure, so as to prevent moisture from penetrating into the interior of the face-up light-emitting device. Furthermore, the first insulating stacked structure 400 acts as a reflective layer that can reflect at least a part of light emitted from the semiconductor stacked structure.

In certain embodiments, the first insulating stacked structure 400 is a multilayer structure, and includes first material layers each of which has a refractive index, and second material layers each of which has a refractive index different from that of each of the first material layers. Also, the first material layers and the second material layers are stacked alternately. For instance, the first insulating stacked structure 400 may include a distributed Bragg reflector (DBR), thereby exhibiting the reflective function. In this embodiment, each of the first material layers may be made of a material having a relatively low refractive index, e.g., silicon oxide, and each of the second material layers may be made of a material having a refractive index higher than that of the first material layer, e.g., titanium oxide. The first insulating stacked structure 400 may be formed by a deposition technique, such as an ion-beam-assisted vapor deposition or a plasma-enhanced chemical vapor deposition (PECVD).

In certain embodiments, the first insulating stacked structure 400 includes X number of layered units each having one of the first material layers and an adjacent one of the second material layers, and 3≤X≤10. In an exemplary embodiment, X is 3. Besides, the first insulating stacked structure 400 has a thickness not less than 500 nm in the laminating direction.

In certain embodiments, the first insulating stacked structure 400 further includes a base layer. The base layer may have a reflectance which is less than that of the semiconductor stacked structure (greater than 2.5). In certain embodiments, the base layer has a thickness ranging from 50 nm 400 nm in the laminating direction. The base layer may be made of, for example, silicon oxide, and may have a thickness greater than other layers included in the first insulating stacked structure 400, so as to guarantee the prevention of moisture penetration.

The base layer may be formed by PECVD, or may be formed initially by PECVD and later by another deposition technique, such as ion-beam-assisted vapor deposition. Adopting the PECVD technique can perfectly ensure the compactness of the base layer so as to attain a good effect of moisture isolation, and also can guarantee good attachment of the base layer to the underlying structure.

In an exemplary embodiment, the base layer of the first insulating stacked structure 400 has a thickness not greater than 400 nm in the laminating direction. In another exemplary embodiment, the thickness of the base layer is not greater than 300 nm, for instance, 250 nm, 200 nm, 100 nm, or 80 nm.

In an exemplary embodiment, the first material layers and the second material layers, which are stacked alternately, are obtained using the ion-beam-assisted vapor deposition. The first material layers and the second material layers thus obtained are comparatively dense.

After that, the first insulating stacked structure 400 is formed with a first through hole 901 and a second through hole 902 to respectively expose the first upper surface of the first wire bonding portion 500a and the second upper surface of the second wire bonding portion 600a. When the face-up light-emitting device is packaged or is mounted on a circuit board, the exposed first upper surface of the first metal electrode 500 and the exposed second surface of the second metal electrode 600 may be used for wire bonding. Furthermore, the first insulating stacked structure 400 may have a first hole-defining wall and a second hole-defining wall. The first hole-defining wall defines the first through hole 901, and has a first top edge which is away from the first metal electrode 500 and which defines a top opening, and a first bottom edge which is in contact with the first metal electrode 500 and which defines a bottom opening. Besides, the second hole-defining wall defines the second through hole 902, and has a second top edge which is away from the second metal electrode 600 and which defines a top opening, and a second bottom edge which is in contact with the second metal electrode 600 and which defines a bottom opening. An area enclosed by the first bottom edge and an area enclosed by the second bottom edge respectively equal to the area of the exposed first upper surface and the exposed second upper surface.

Subsequently, a reflecting structure 900 is formed on the second surface of the substrate 100. The reflecting structure 900 may reflect light back to the substrate 100, so that the light may exit the face-up light-emitting device through its side surface. In addition, the reflecting structure 900 may include first reflecting layers each of which has a refractive index, and second reflecting layers each of which has a refractive index different from that of each of the first reflecting layers. The first reflecting layers and the second reflecting layers are alternately disposed. In certain embodiments, each of the first insulating stacked structure 400 and the reflecting structure 900 incudes a distributed Bragg reflector (DBR). The distributed Bragg reflectors (DBRs) may be made of, for instance, a combination of silicon oxide and titanium oxide.

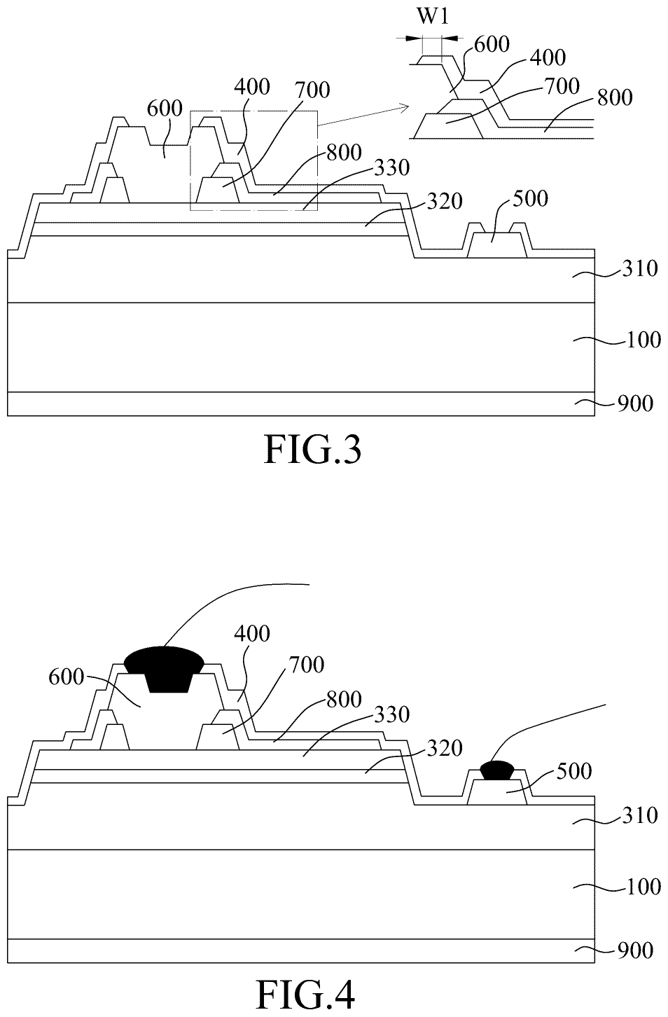

Lastly, a dicing procedure is performed as described below to obtain the face-up light-emitting device. First, breaking points are formed inside the substrate 100 using a laser, followed by fracturing the first insulating stacked structure 400, the first semiconductor layer 310, the substrate 100, and the reflecting structure 900, from a top surface of the first insulating stacked structure 400 that overlies the first semiconductor layer 310 along the laminating direction by an external force, so as to obtain the face-up light-emitting device as shown in FIGS. 2 to 3.

Referring to FIGS. 2 to 3, the first surface of the substrate 100 is thoroughly covered by the first semiconductor layer 310. Also, a top surface of the first semiconductor layer 310 that is not occupied by the first metal electrode 500, a side wall of the active layer 320, a side wall of the second semiconductor layer 330, a top surface of the transparent conductive layer 800, a part of the first metal electrode 500 and a part of the second metal electrode 600 are covered by the first insulating stacked structure 400.

As mentioned above, the first insulating stacked structure 400 may be a multilayer structure having reflexivity, which can reduce the proportion of light output from a front side of the face-up light-emitting device and enhance the proportion of large-angle light emission. The thicker the layered units are and the more pairs the layered units have, the higher the reflectance of the first insulating stacked structure 400 is. Thus, light from various angles can be reflected.

However, a relatively thick first insulating stacked structure 400 is not necessary, and the reason is that an overly thick insulating stacked structure 400 may result in greater depth of the first and second through holes 901, 902, which may affect the wire-bonding yield. Referring to FIG. 4, a metal wire practically used for external electrical connection is, for instance, a gold wire. Two metal wires are shown in FIG. 4 and are respectively connected to the first metal electrode 500 and the second metal electrode 600. The metal wire connected to the second metal electrode 600 is exemplarily illustrated below. The metal wire has a blob portion which has a spherical or nearly spherical shape, and is connected to the second upper surface of the second wire bonding portion 600a exposed from the second through hole 902 and a portion of the first insulating stacked structure 400 that defines the second through hole 902. The thicker the first insulating stacked structure 400 is, the less the firmness of the blob portion on the second upper surface is. That is, the height of the first insulating stacked structure 400 may affect the firmness of bonding.

Therefore, in order to ensure the reliability of wire bonding of the first and second metal electrodes 500, 600, in certain embodiments, the thickness of the first insulating stacked structure 400 is not greater than 1 μm according to industrial requirements. In an exemplary embodiment, the thickness of the first insulating stacked structure 400 ranges from 0.5 μm to 1.0 μm. For example, the thickness of the first insulating stacked structure 400 may be 0.9 μm, 0.8 μm, 0.7 μm, 0.6 μm, or 0.5 μm. Besides, the number of layered unit of the first insulating stacked structure 400 may be controlled, e.g., not greater than 10 layered units.

An insulating layer used in a conventional face-up light-emitting device is a single layer of silicon dioxide, and a through hole of the insulating layer is formed by a wet etching technique. During the wet etching, both horizontal and vertical etching might be simultaneously performed, which tends to result in an exceedingly large through hole. Thus, the through hole might have a dimension larger than that of an upper surface of a wire bonding portion of an electrode of the conventional face-up light-emitting device, so that a side wall of the wire bonding portion of the electrode of the conventional face-up light-emitting device might be exposed from the through hole. As a result, moisture would be very likely to penetrate into the internal of the conventional face-up light-emitting device through the exposed side wall, thereby affecting electricity or causing failure of the face-up light-emitting device.

In this embodiment, to form the first through hole 901 and the second through hole 902, the first insulating stacked structure 400 which includes the first material layers made of silicon oxide and the second material layers made of titanium oxide may be subjected to a dry etching technique. The dry etching is anisotropic etching, and the position and width of each of the first through hole 901 and the second through hole 902 may be properly controlled, thereby ensuring that side walls of the first wire bonding portion 500a and the second wire bonding portion 600a will not be exposed from the first and second through holes 901, 902 so as to provide good air/moisture sealing effect.

By using the dry etching technique to form the first and second through holes 901, 902, a horizontal distance between the first top edge of the first hole-defining wall and a periphery of the first upper surface of the first wire bonding portion 600a may range from 2 μm to 10 μm, e.g., from 2 μm to 8 μm, thereby ensuring the coverage and air/moisture sealing effect of the first insulating stacked structure 400 on the first upper surface. Similarly, a horizontal distance (W1) between the second top edge of the second hole-defining wall and a periphery of the second upper surface of the second wire bonding portion 600b may range from 2 μm to 10 μm, e.g., from 2 μm to 8 μm, thereby ensuring the coverage and air sealing effect of the first insulating stacked structure 400 on the second upper surface. Besides, in order to avoid the bottom of the through holes having too narrow dimensions that may affect the firmness of bonding, the horizontal distance is not greater than 8 μm.

In certain embodiments, for each of the first through hole 901 and the second through hole 902, the bottom opening is smaller than the top opening. In addition, the first hole-defining wall and the second hole-defining wall may be curved or straight. An angle between the first hole-defining wall and the first upper surface of the first wire bonding portion 500a may be greater than 120°, and an angle between the second hole-defining wall and the second upper surface of the second wire bonding portion may be greater than 120°. Due to the dry etching technique, the foregoing angles may not be too small, for instance, ranging from 120° to 150°.

In certain embodiments, the face-up light-emitting device after dicing has a thickness not greater than 200 nm. The face-up light-emitting device having too large thickness may lead to light absorption.

Furthermore, the first insulating stacked structure 400 has to cover the top surface of the first semiconductor layer 310 that is not occupied by the first metal electrode 500 so as to protect the top surface of the first semiconductor layer 310. A periphery of the first insulating stacked structure 400 is flush with a periphery of the first semiconductor layer 310, and the first insulating stacked structure 400 is the uppermost layer of the face-up light-emitting device and has a smaller thickness so that, when the width and the length of the substrate 100 are relatively large, chip warpage, chip fragmentation, poor chip yield caused by stress may be avoided.

A second embodiment of the face-up light-emitting device according to the disclosure is generally similar to that of the first embodiment, except for the differences described below.

In the second embodiment, the first insulating stacked structure 400 may realize that a part of light emitted from the semiconductor stacked structure is reflected by the first insulating stacked structure 400 and emits outwardly through a periphery of the face-up light-emitting device, and a part of the light emits outwardly through the first insulating stacked structure 400, thereby ensuring brightness of the face-up light-emitting device.

In certain embodiments, the semiconductor stacked structure emits light having a wavelength ranging from 430 nm to 460 nm.

The aforementioned light having the wavelength ranging from 430 nm to 460 nm includes light beam having a first incident angle with a normal line to the first insulating stacked structure 400, and light beam having a second incident angle with the normal line. The light beam having the first incident angle may be referred to as a first light, and the light beam having the second incident angle may be referred to as a second light. In certain embodiments, the first incident angle of the first light ranges from 0° to 10°. The first insulating stacked structure 400 is capable of reflecting the first light, and thus has the ability to reduce light leakage from the front side of the face-up light-emitting device, thereby improving the light output ratio of the second light.

In an exemplary embodiment, the first insulating stacked structure 400 has a reflectance greater than 90% to the first light. The first incident angle of the first light may be 0° or 10°.

In addition, the first insulating stacked structure 400 may have a low reflectance to the second light, which may enable at least a part of the second light to pass through the first insulating stacked structure 400. For instance, the first insulating stacked structure 400 has a relatively low reflectance to the second light having the second incident angle greater than 30°, thereby enhancing the light efficiency of the face-up light-emitting device and reducing light loss caused by light reflection back to the interior of the face-up light-emitting device. In an exemplary embodiment, the second incident angle of the second light ranges from 40° to 60°. In another exemplary embodiment, the second incident angle of the second light ranges from 40° to 50°. In yet another exemplary embodiment, the second incident angle of the second light ranges from 50° to 60°. The first insulating stacked structure 400 may have a reflectance less than 90% to at least a part of the second light., e.g., less than 80%, less than 70%, less than 60%, or even less than 50%.

In order to ensure that the second light having a large incident angle is transmissible through the first insulating stacked structure 400, the first insulating stacked structure 400 may have a comparatively lower reflectance to a light having a wavelength ranging from 500 nm to 700 nm and having an incident angle ranging from 0° to 10°. To be more specific, in an exemplary embodiment, the reflectance to the light having the wavelength ranging from 500 nm to 700 nm and having the incident angle ranging from 0° to 10° is less than 50%; in another exemplary embodiment, the reflectance is less than 30%.

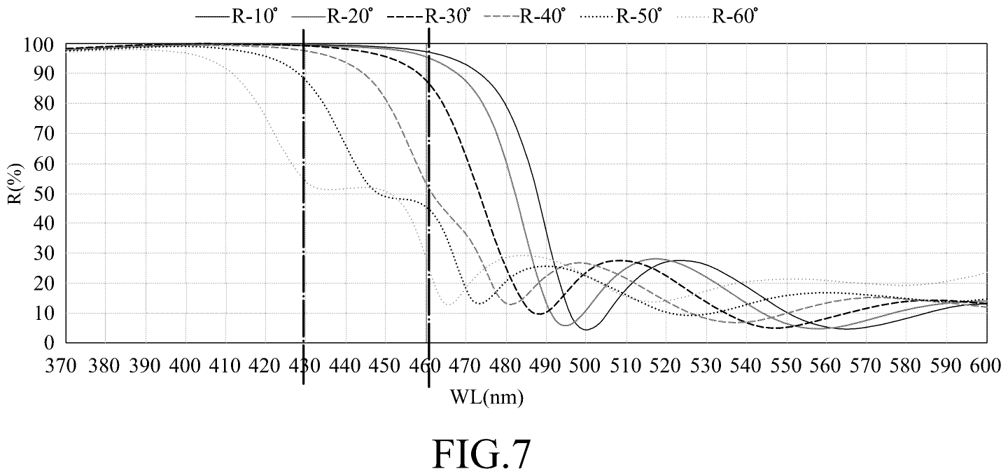

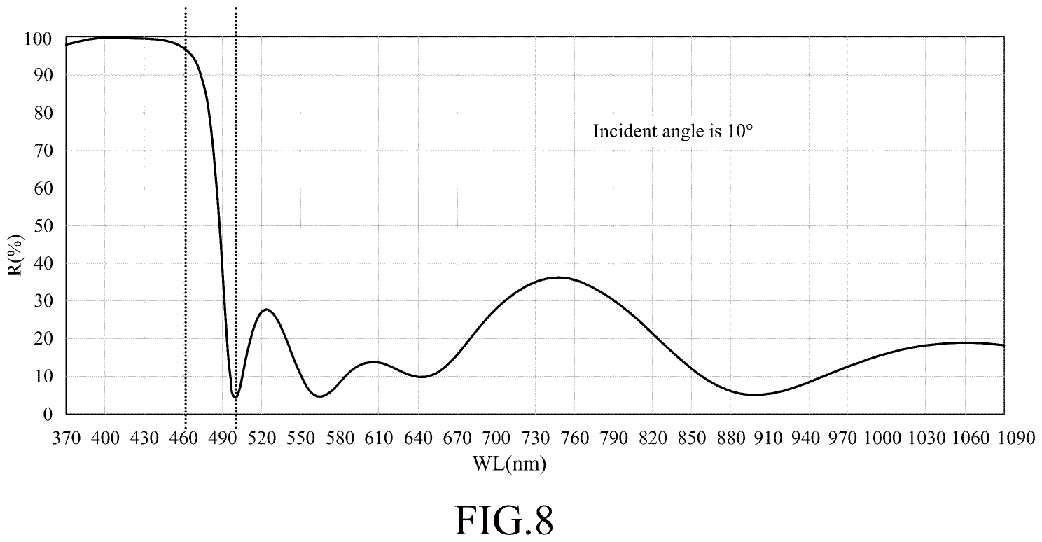

Referring to FIGS. 7 and 8, in this embodiment, the first insulating stacked structure 400 has a reflectance greater than or equal to 97% to a light having a wavelength ranging from 430 nm to 460 nm and having an incident angle of 10°. For a light having a wavelength within the same range and having an incident angle of 20°, the first insulating stacked structure 400 has a reflectance less than 97% to a part of the light, and the total light reflectance is greater than 95%. Moreover, for a light having a wavelength within the above-mentioned range and having an incident angle of 30°, the first insulating stacked structure 400 has a reflectance less than 95% to a part of the light, but the total light reflectance is greater than 85%. In addition, for a light having a wavelength within the range mentioned in the foregoing and having an incident angle of 40°, the first insulating stacked structure 400 has a reflectance less than 85% to a part of the light, however, the total light reflectance is greater than 50%. Furthermore, for a light having a wavelength within the above-mentioned range, the first insulating stacked structure 400 has a reflectance ranging from 40% to 90% to the light having an incident angle of 50°, and has a reflectance ranging from 20% to 60% to the light having an incident angle of 60°.

For accomplishing the aforesaid first light having high reflectance and the aforesaid second light having high transmittance, the first insulating stacked structure 400 in this embodiment according to the disclosure have the following characteristics.

The first material layers are made of a low refractive index material, and the second material layers are made of a high refractive index material. In an exemplary embodiment, the first material layers are made of silicon oxide that has a refractive index ranging from 1.4 to 1.5, and the second material layers are made of titanium oxide that has a refractive index ranging from 2.4 to 2.6.

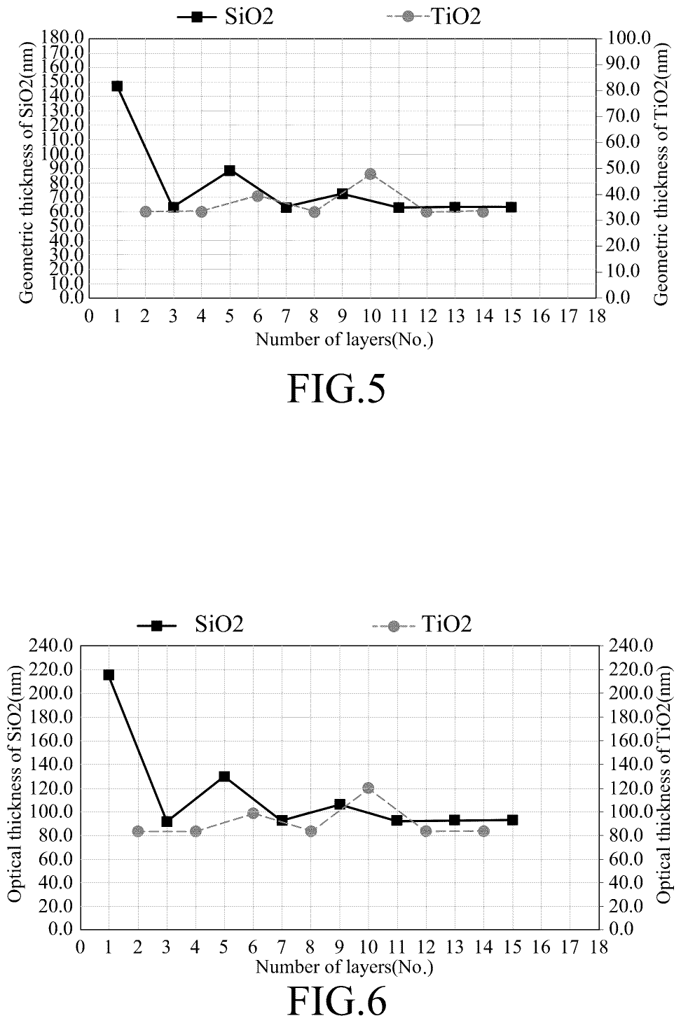

As shown in FIGS. 5 and 6, in this embodiment, the first insulating stacked structure 400 includes the base layer of SiO₂ (i.e., layer 1), seven first material layers of SiO₂ (i.e., layers 3, 5, 7, 9, 11, 13 and 15), and seven second material layers of TiO₂ (i.e., layers 2, 4, 6, 8, 10, 12 and 14). In this embodiment, each of the first material layers has a geometrical thickness ranging from 50 nm to 100 nm and an optical thickness ranging from 75 nm to 140 nm.

As shown in FIGS. 5 and 6, in this embodiment, each of the second material layers has a geometrical thickness ranging from 30 nm to 60 nm and an optical thickness ranging from 75 nm to 140 nm.

It is noted that FIGS. 7 and 8 are simulation graphs obtained using first insulating stacked structure 400 that has the structure and composition shown in FIGS. 5 and 6, and a gallium nitride as incident medium.

In an exemplary embodiment, the topmost layer of the first insulating stacked structure 400 is one of the first material layers which is made of silicon oxide. That is to say, the layer of the first insulating stacked structure 400 that is farthest from the semiconductor stacked structure is one of the first material layers.

The first insulating stacked structure 400 includes at least 3 layered units. If the first insulating stacked structure 400 has only 1 or 2 layered unit(s), its reflectance to the aforesaid first light may be too low, for instance, lower than 90%, causing the light emitting from the front side of the face-up light-emitting device to be extremely bright, and results in uneven light distribution. When the first insulating stacked structure 400 has 3 layered units, a reflectance greater than 90% to the foregoing first light may be obtained. However, in order to avoid the first insulating stacked structure 400 being too thick, in certain embodiments, the first insulating stacked structure 400 includes up to 10 layered units. In an exemplary embodiment, the first insulating stacked structure 400 includes 5 to 8 layered units, which guarantees a reflectance greater than 85% to a light having a wavelength ranging from 430 nm to 460 nm and having an incident angle ranging from 0° to 30°. Nevertheless, too many layered units may lead to more reflections of the light having small incident angles, resulting in a decrease in brightness.

In comparison with a conventional distributed Bragg reflector (DBR), the first insulating stacked structure 400 in this embodiment has a relatively high reflectance to a light emitted from the semiconductor stacked structure and having a small incident angle, and has a relatively low reflectance to a light emitted from the semiconductor stacked structure and having a large incident angle, so as to ensure that the face-up light-emitting device has a greater brightness.

The reflecting structure 900 has a high reflectance to the light emitted from the semiconductor stacked structure of the face-up light-emitting device. In certain embodiments, the reflecting structure 900 has a reflectance greater than 90% to a light having a wavelength ranging from 400 nm to 700 nm and having an incident angle ranging from 0° to 10°.

In an exemplary embodiment, the reflecting structure 900 has a geometrical thickness greater than that of the first insulating stacked structure 400, e.g., at least two times of the geometrical thickness of the first insulating stacked structure 400. In another exemplary embodiment, the reflecting structure 900 has the geometrical thickness greater than or equal to four times of the geometrical thickness of the first insulating stacked structure 400, which may allow the reflecting structure 900 to have a higher reflectance to the light that is emitted from the semiconductor stacked structure, that penetrates through the substrate 100 (e.g., a transparent substrate), and that then arrives at a surface or in an interior of the reflecting structure 900, thereby enhancing light efficiency.

In certain embodiments, the reflecting structure 900 includes Y number of layer units each having one of the first reflecting layers and an adjacent one of the second reflecting layers, and Y>X. In other embodiments, Y is greater than or equal to two times of X. In an exemplary embodiment, Y≥15, e.g., 30≤Y≤60. Specifically, the reflecting structure 900 may have a thickness ranging from 3 μm to 6 μm.

A third embodiment of the face-up light-emitting device according to the disclosure is generally similar to that of the first embodiment, except for the differences described below.

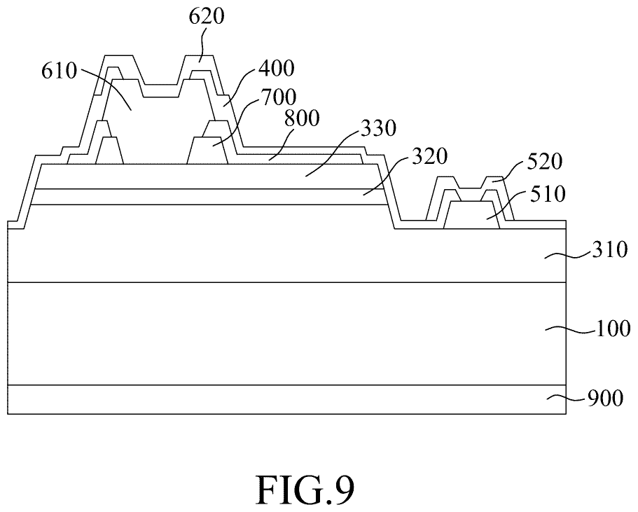

Referring to FIG. 9, in order to protect the first insulating stacked structure 400 from cracking due to a bonding force of the metal wire, in this embodiment, the first metal electrode 500 includes an inner metal layer 510 disposed below the first insulating stacked structure 400, and an outer metal layer 520 disposed above the first insulating stacked structure 400 and electrically connected to the inner metal layer 510, and the second metal electrode 600 includes an inner metal layer 610 disposed below the first insulating stacked structure 400, and an outer metal layer 620 disposed above the first insulating stacked structure 400 and electrically connected to the inner metal layer 610. Each of the inner metal layers 510, 610 may include an adhesive layer, a reflective layer, and a blocking layer from bottom to top. In addition, each of the outer metal layers 520, 620 may include a metal bonding layer. In the third embodiment, the adhesive layer, the reflective layer, the blocking layer, and the metal bonding layer may have structures and compositions the same as those described in the first embodiment. Each of the outer metal layers 520, 620 may further include an adhesive layer made of, e.g., titanium, for improving adhesion of the metal bonding layer on the first insulating stacked structure 400.

An embodiment of a display device according to the disclosure includes a backlight module. The backlight module includes a circuit substrate and at least one face-up light-emitting device. The circuit substrate may be a chip-on-board (COB) substrate or a chip-on-glass (COG) substrate. The face-up light-emitting device may be any one of aforesaid face-up light-emitting device according to the disclosure, and is mounted on the circuit substrate by means of a face-up mounting technique. There may be hundreds, thousands, or tens of thousands of the face-up light-emitting devices on the circuit substrate.

The display device may further include a fluorescent material, such as a fluorescent powder, or a quantum dot (QD) material which can realize light conversion and further emission.

The display device may be a backlight device of, for example, a TV, a monitor, a computer, or a notebook.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A face-up light-emitting device, comprising:
a substrate which has a first surface and a second surface opposite to said first surface;
a semiconductor stacked structure which is disposed on said first surface and is capable of emitting light; and
a first insulating stacked structure which is disposed on said semiconductor stacked structure and which includes first material layers each of which has a refractive index, and second material layers each of which has a refractive index higher than that of each of said first material layers, said first insulating stacked structure having a geometric thickness which ranges from 500 nm to 1000 nm, said first material layers and said second material layers being stacked alternately.

2. The face-up light-emitting device as claimed in claim 1, further comprising a first metal electrode and a second metal electrode which are disposed on said semiconductor stacked structure, said first metal electrode including a first wire bonding portion which has a first upper surface, said second metal electrode including a second wire bonding portion which has a second upper surface, said first insulating stacked structure covering said first metal electrode and said second metal electrode, and having through holes that respectively expose said first upper surface and said second upper surface.

3. The face-up light-emitting device as claimed in claim 2, wherein said first insulating stacked structure has a first hole-defining wall and a second hole-defining wall, said first hole-defining wall defining said first through hole and having a first top edge, said second hole-defining wall defining said second through hole and having a second top edge, a horizontal distance between said first top edge and a periphery of said first upper surface ranging from 2 μm to 10 μm, a horizontal distance between said second top edge and a periphery of said second upper surface ranging from 2 μm to 10 μm.

4. The face-up light-emitting device as claimed in claim 1, wherein said first insulating stacked structure has a reflectance greater than 90% to a light having a wavelength ranging from 430 nm to 460 nm and having an incident angle ranging from 0° to 10°.

5. The face-up light-emitting device as claimed in claim 4, wherein said first insulating stacked structure has a reflectance less than 50% to a light having a wavelength ranging from 500 nm to 700 nm and having an incident angle ranging from 0° to 10°.

6. The face-up light-emitting device as claimed in claim 1, wherein said first insulating stacked structure includes X number of layer units each having one of said first material layers and an adjacent one of said second material layers, and 3≤X≤10.

7. The face-up light-emitting device as claimed in claim 1, wherein said first insulating stacked structure further includes a base layer which has a geometric thickness ranging from 50 nm to 400 nm.

8. The face-up light-emitting device as claimed in claim 1, wherein each of said first material layers has a geometric thickness ranging from 50 nm to 100 nm, and each of said second material layers has a geometric thickness ranging from 30 nm to 60 nm.

9. The face-up light-emitting device as claimed in claim 6, further comprising a reflecting structure disposed on said second surface of said substrate, said reflecting structure including first reflecting layers and second reflecting layers stacked alternately, and having a geometric thickness greater than that of said first insulating stacked structure.

10. The face-up light-emitting device as claimed in claim 9, wherein said reflecting structure includes Y number of layer units each having one of said first reflecting layers and an adjacent one of said second reflecting layers, and Y>X.

11. The face-up light-emitting device as claimed in claim 10, wherein said reflecting structure has a reflectance greater than 90% to a light having a wavelength ranging from 400 nm to 700 nm and having an incident angle ranging from 0° to 10°.

12. The face-up light-emitting device as claimed in claim 10, wherein the geometric thickness of said reflecting structure is greater than two times of the geometric thickness of said first insulating stacked structure.

13. The face-up light-emitting device as claimed in claim 10, wherein the geometric thickness of said reflecting structure ranges from 3 μm to 6 μm and Y≥15.

14. The face-up light-emitting device as claimed in claim 10, wherein 30≤Y≤60.

15. The face-up light-emitting device as claimed in claim 1, wherein said substrate has a thickness greater than 80 μm.

16. The face-up light-emitting device as claimed in claim 1, further comprising a first metal electrode and a second metal electrode which are disposed on said semiconductor stacked structure, said first metal electrode including an inner metal layer disposed below said first insulating stacked structure, and an outer metal layer disposed above said first insulating stacked structure and electrically connected to said inner metal layer, said second metal electrode including an inner metal layer disposed below said first insulating stacked structure, and an outer metal layer disposed above said first insulating staked structure and electrically connected to said inner metal layer.

17. The face-up light-emitting device as claimed in claim 1, wherein said semiconductor stacked structure includes a first semiconductor layer, an active layer, and a second semiconductor layer that are disposed on said substrate in such order.

18. The face-up light-emitting device as claimed in claim 17, wherein a periphery of said first insulating stacked structure is flush with a periphery of said first semiconductor layer.

19. The face-up light-emitting device as claimed in claim 18, wherein said substrate has a length and a width, said length to said width being in a ratio not less than 2:1.

20. A display device comprising a face-up light-emitting device as claimed in claim 1.
